(19) United States
(12) Patent Application Publication
(10) Pub. No.: US 2008/0157640 A1
(43) Pub. Date: Jul. 3, 2008

(54) Cabinet Facilitating Storage, Transport, and Assembly and Its Packing Method

(75) Inventors: Li Chen, Guangdong (CN); Rensheng Fu, Guangdong (CN)

Correspondence Address: GLOBAL IP SERVICES, 7285 W. Eagle Court, Winton, CA, 95388, US

(73) Assignee: SHENZHEN TOTEN PRECISION MACHINERY CO., LTD., Shenzhen (CN)

(21) Appl. No.: 11/910,413

(22) PCT Filed: Mar. 30, 2005
(86) PCT No.: PCT/CN2005/000419

§ 371 Date: Oct. 1, 2007

(51) Int. Cl. A47B 47/00; H05K 5/00

(52) U.S. Cl. 312/264; 53/471

(57) ABSTRACT

A cabinet facilitating storage, transport, and assembly, and its package method, are provided. The cabinet consists of 2 bounding-frame subassemblies, a door, a back-board, connecting-beams, and screws. The bounding-frame subassembly is constituted of a bounding-frame, and a panel, mounting-beams, device-mounting battens etc., which are mounted on the bounding-frame in advance. Each of the 4 corner ends inside 2 bounding-frame subassemblies is provided with an embedding head, which is inserted into and engaged with the connecting-beam. It is easy to assemble the cabinet at the spot, because the engaging structure of 2 bounding-frame subassemblies and the connecting-beams can be fixed with 8 screws so that the cabinet's frame can be assembled quickly. When packed, it is possible to put the door, the back-board, the connecting-beams, the screws etc., into the space S formed by 2 bounding-frame subassemblies. Since the package formed in this manner has a great strength resisting a pressure, it can insure the parts therein not to be damaged. It is also possible to superpose plurality of such packages, so that transporting or storing space can be reduced greatly.

### FIELD OF THE INVENTION

The present invention relates to a cabinet, and more specifically to a cabinet facilitating storage, transport, and assembly, and its packing method.

### BACKGROUND OF THE INVENTION

Office automation systems, telecommunication systems, exchanging systems, electric systems or control systems are usually consisted of several separate equipments. In order to facilitate management of the equipments which constitute the system equipment, the sellers offer cabinets that are convenient for centralized placements and facility operations. The existing cabinets shaped in erect rectangle are usually consisted of a rectangular frame, a door, device-mounting battens etc. At present, this kind of cabinets are assembled into a whole system for consignment, or transported in subassemblies. The complete system package (FIG. 8) is bulky in transport and storage, and costs a lot. The subassemblies are assembled into a whole system after transported to the spot. This can reduce the cost of cabinet transport and storage in an efficient way. However, the existing cabinets, which are assembled by subassemblies, are easy to cause damage in transport for less considering the stacking force, and it can't reduce the stack space efficiently. As there are lots of subassemblies at the spot, and the assembling process is very complex, the labor cost is very expensive.

### SUMMARY OF THE INVENTION

The present invention mainly provides a cabinet facilitating storage, transport, and assembly, and its packing method, which overcomes the shortage of inconvenience for packing, stacking, and assembling after the package are tore open. The cabinet with this kind of structure can reduce the package space largely, and can be assembled quickly at the spot.

The present invention provides a cabinet facilitating storage, transport and assembly which comprise a frame, a door, a back-board and screws, wherein
a. The frame is consisted of two bounding-frame subassemblies, four connecting-beams, and eight screws, said screws being used to connect the bounding-frame subassemblies and the connecting-beams together.
b. The bounding-frame subassembly is constituted of a bounding-frame, and a panel, mounting beams, device-mounting battens etc., all of which are mounted on the bounding-frame in advance.
c. Each of the four corner ends inside two bounding-frame subassemblies is provided with an embedding head, which is inserted into and engaged with the connecting-beam. Each of the four corner ends inside the bounding-frame corresponding to the embedding heads is provided with a stepped through hole for a screw to insert and screw down therein.
d. The both ends of a connecting-beam are provided with counter bores corresponding to the embedding heads. The bottom surface of the counter bores are provided with screw holes corresponding to the stepped through holes at the four corner ends inside the bounding-frame.

The present invention presents a packing method of a cabinet facilitating storage, transport and assembly, which comprises the following steps: putting a bounding-frame subassembly inside a package box with its embedding heads upwards; then, putting a door, a back-board, connecting-beams, screws and other components on the bounding-frame subassembly; next, covering another bounding-frame subassembly on the previous bounding-frame subassembly with its embedding heads facing downwards. The embedding heads at the four corner ends of the folded bounding-frame subassemblies are engaged to shape a flat box which is composed of two bounding-frame subassemblies. The final step is packing the flat box.

The design principle of the cabinet is: preassemble rails, pillars and connecting-blocks at the four corner ends of a frame into a bounding-frame in factory, and then mount on the bounding-frame with a door, mounting-beams, and device-mounting battens etc. to form a bounding-frame subassembly. When packing, two bounding-frame subassemblies are placed in opposite stacks, and then put other subassemblies into the space, which is constructed by the embedding heads of the connecting blocks at the four corner ends inside the bounding-frame. When the package is transported to the assembly spot, using the embedding heads of the connecting-blocks inside the four corner ends of the bounding-frame to connect the two bounding-frame subassemblies and the connecting-beams, and then assemble them into a solid frame. The inserting and engaging structure between two bounding-frame subassemblies and connecting-beams can be fixed with eight screws, premade stepped through holes and screw holes so that the cabinet's frame can be assembled quickly. The last step to finish a cabinet is inserting other doors and boards into the right holes in the frame.

Compared to conventional cabinets and their packing methods, the present invention has some advantages. It reduces package volume a great lot. It's easy to assemble a cabinet quickly at a spot using eight screws to fix the engaging structure between two bounding-frame subassemblies and connecting-beams. It can fulfill the requirement of quick assembly. The cabinet package, which is packed by the present method, can suffer great pressure, and can make sure that the subassemblies inside the package can stay away from damage. The cabinet packages can be placed in stack so as to reduce volume largely when they are transported or stored.

The present invention about a cabinet facilitating storage, transport, and assembly, and its packing method is described in detail in the following figures.

### BRIEF DESCRIPTION OF THE DRAWINGS

FIG. 1 shows an exploded structure of a cabinet facilitating storage, transport, and assembly;

FIG. 2a shows an exploded structure of a bounding-frame of a quick assembled cabinet facilitating storage, transport, and assembly in FIG. 1;

FIG. 2b shows an exploded structure of an assembled bounding-frame subassembly;

FIG. 2c shows a structure of a bounding-frame subassembly;

FIG. 3a shows an exploded structure of an assembled frame;

FIG. 3b shows a structure of a frame;

FIG. 3c shows a structure of an assembled cabinet;

FIG. 4 shows an exploded structure of an assembly of a bounding-frame and a connecting-beam;

FIG. 5a shows an exploded structure of two folded bounding-frame subassemblies;

FIG. 5b shows a structure of two folded bounding-frame subassemblies;

FIG. 6a shows a packing process of a cabinet facilitating storage, transport, and assembly in FIG. 1;

FIG. 6b shows a packed cabinet facilitating storage, transport, and assembly in FIG. 1;

FIG. 7 shows several cabinet packages placed in stack;

FIG. 8 shows a congener cabinet package.

### DETAIL DESCRIPTION OF THE INVENTION

### EMBODIMENT

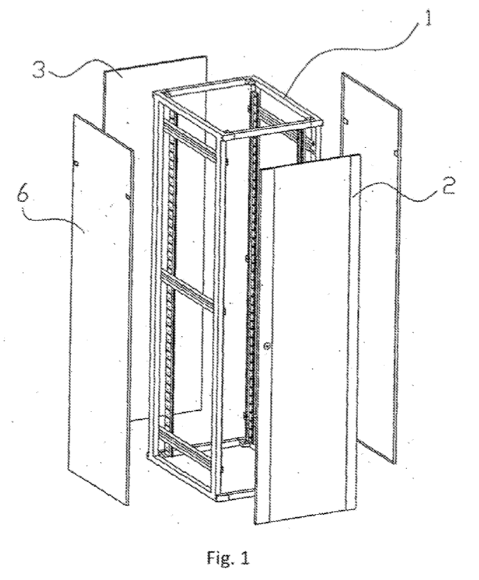

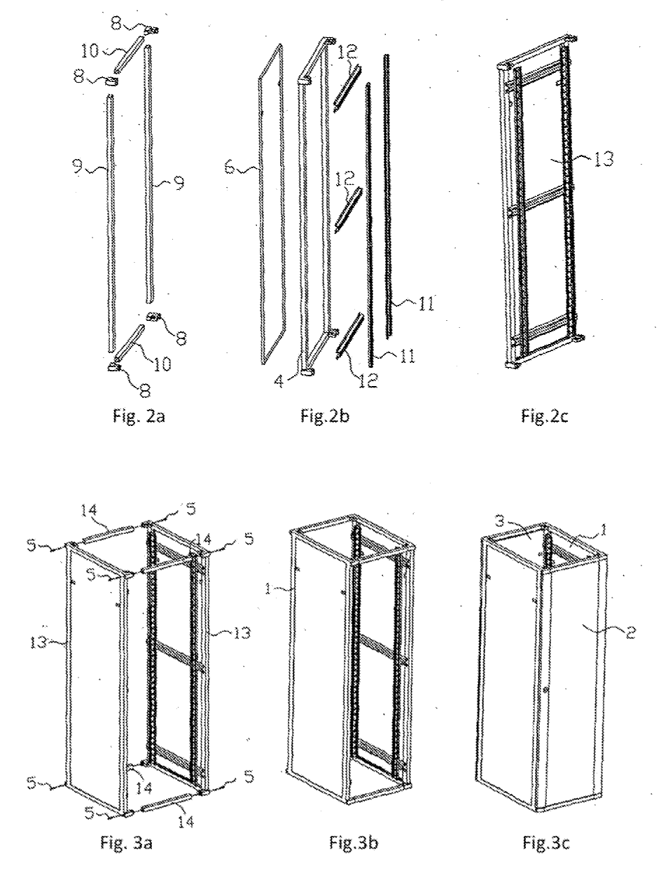

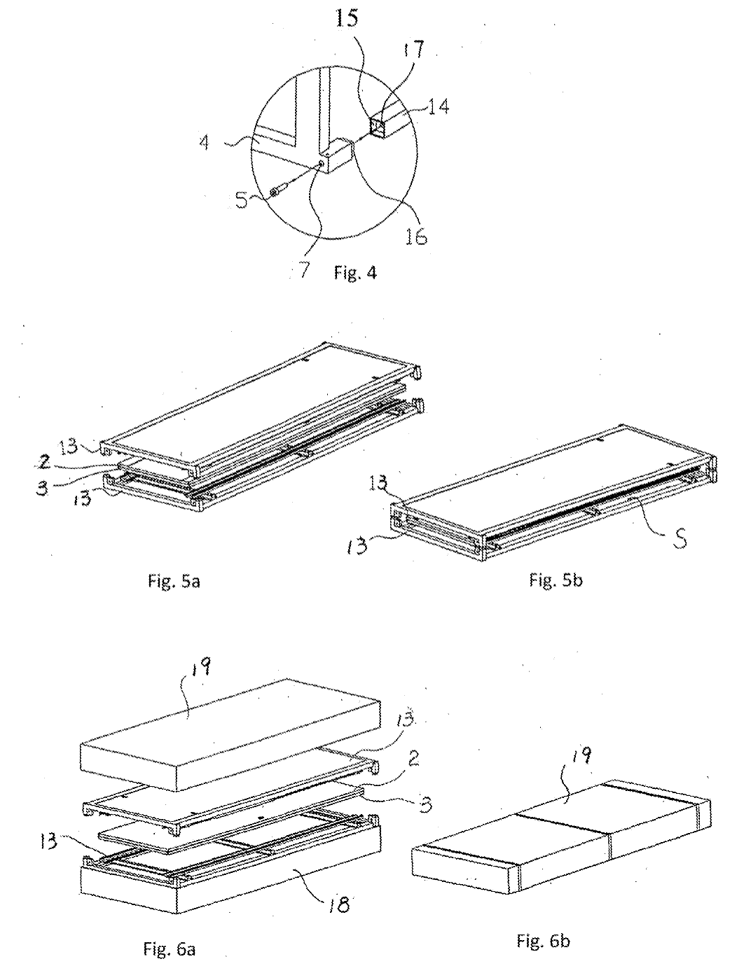

As shown in FIG. 1, a cabinet facilitating storage, transport, and assembly comprises a frame 1, a door 2, a back-board 3 and a panel 6. The frame 1 is consisted of two bounding-frame subassemblies 13, four connecting-beams 14 and eight screws 5 (shown in FIG. 3b). The bounding-frame subassembly is composed of a bounding-frame 4 and a panel 6, mounting-beams 12, device-mounting battens 11 etc, all of which are mounted on the bounding-frame 4 in advance (shown in FIG. 2b) to form the bounding-frame subassembly (shown in FIG. 2c). The bounding-frame 4 comprises two pillars 9 and two rails 10, all of which are connected by four connecting-blocks 8 (shown in FIG. 2a). The outside part of a connecting block 8 corresponding to the four corner ends inside a bounding-frame 4 is an embedding head which can be inserted into and engaged with a connecting-beam 14 (shown in FIG. 4). The four corner ends of the bounding-frame 4 corresponding to the embedding heads 16 are provided with stepped through holes 7 for the screws 5 to fix (shown in FIG. 4). The connecting-beam 14 is tubular, and its two sides are provided with counter bores 15 matching embedding heads 16. The ground surface of a counter bores 15 are provided with screw holes 17 corresponding to the stepped through holes 7 at the four corner ends of the bounding-frame 4. The embedding heads are polygonal convex heads matching polygonal convex counter bores 15 on the both sides of the connecting-beam 14. This kind of assembly is good for the steady connection.

The subassemblies of a cabinet comprise: two bounding-frame subassemblies constituted of two panels 6, device-mounting battens 11, mounting-beams 12 etc., which is mounted in advance, a door 2, a back-board 3, four connecting-beams 14 and eight screws 5. The embedding heads of two bounding-frame subassemblies are put together in opposite stacks (shown in FIG. 5a) to form the space S (shown in FIG. 5b).

When assembled at the spot, the embedding heads 16 at the four corners inside a bounding-frame 4 are inserted into the counter bores 15 on the both sides of connecting-beams 14 respectively to form a solid frame 1, and then fix eight screws on the stepped through holes 7 at the four corner ends inside two bounding-frame subassemblies 13 so that the two bounding-frame subassemblies and the four connecting-beams could be connected tightly to form a cabinet 1 (shown in FIG. 3b). Door 2 and back-board 3 are both inserted into the right place on frame 1 without a screw to finish the assembling process (shown in FIG. 3c).

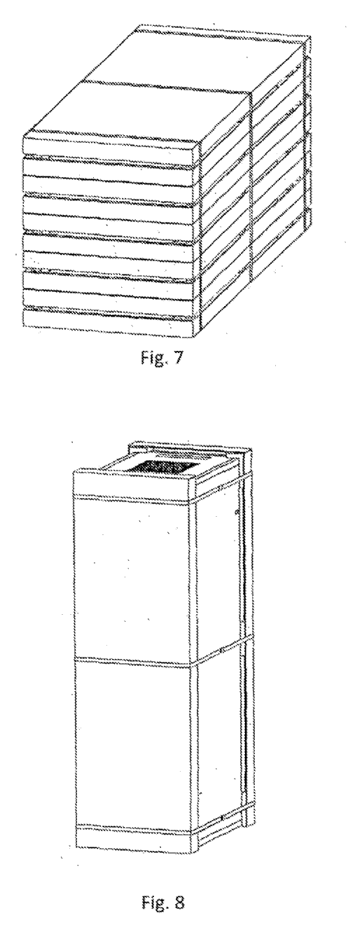

The present packing method comprises several steps (shown in FIG. 6a). Firstly, put a bounding-frame subassembly 13 into a package box 18 with its embedding heads 16 upwards, and then put a door 2, a back-board 3, connecting-beams 14, screws 5 and other subassemblies on the previous bounding-frame subassembly 13. After that, cover another bounding-frame subassembly 13 upon the previous bounding-frame subassembly 13 with its embedding heads 16 downwards. The embedding heads of the two folded bounding-frame subassemblies 13 are placed in opposite stack. Hence, the gravity of the upper bounding-frame subassembly 13 is passed vertically through the embedding heads 16 at the 4 corner ends to the embedding heads 16 at the four corner ends inside the lower bounding-frame subassembly 13. This kind of placement forms a flat box that can stand high pressure. The final step is to put on the cover board 19 and pack.

With this cabinet package described in the present invention, the flat box formed by two bounding-frame subassemblies can bear high pressure, and the inside door 2, back-board 3, connecting-beams 14 etc. can stay away from extrusion or crash. The cabinet package can be placed in stack safely by passing the gravity of the cabinet packages through the embedding heads at the four corners inside bounding-frame subassemblies to the ground, and there is no extrusion between the upper cabinet package and the lower cabinet package. With this kind of package and placement, the transport space and storage space can be saved largely.

Compared to the conventional congener cabinet packages, the present cabinet packages using the previous described packing method save a great space, and can be placed in stack without damaging the subassemblies inside the flat frames.

1. A cabinet facilitating storage, transport and assembly, comprising: a frame, a door, a back-board and a plurality of screws, wherein:
a. the frame is constructed of two bounding-frame subassemblies and four connecting-beams, all of which are connected by screws;
b. the bounding-frame subassembly is constructed of a bounding-frame, a panel, plural mounting-beams, and device-mounting battens, the panel, mounting-beams and device-mounting battens being mounted on the bounding-frame in advance;
c. the bounding-frame subassembly has four corner ends with embedding head having stepped through hole for guiding and securing the screw;
d. each end of the connecting-beam has bore with screw hole for receiving the embedding head,;
e. the connecting beam can connect the two bounding-frame subassemblies to become the cabinet by inserting the embedding head into the bore of the connecting beam and tweaking the screw into the screw hole.

2. The cabinet according to claim 1, wherein the bounding-frame is consisted of two pillars and two rails, which are connected by four connecting-blocks to form the bounding-frame, the embedding head is inserted into and engaged with the bore of the connecting-beam.

3. The cabinet according to claim 1, wherein the embedding heads are polygonal convex heads, and the bores on the both ends of the connecting-beam are polygonal convex bores which are suitable for the embedding heads.

4. A method of packing cabinet facilitating storage, transport, and assembly according to claim 1, comprising following steps:
putting a bounding-frame subassembly into a package box with its embedding heads facing upwards; putting a door, a back-board , plural connecting-beams , screws and other subassemblies on the bounding-frame subassembly; covering another bounding-frame subassembly (13) upon the previous bounding-frame subassembly (13) with its embedding heads facing downwards so that the embedding heads of the two folded bounding-frame subassemblies are placed in opposite stacks to form a flat box, and putting on the cover board (19) and packing.

5. The cabinet according to claim 1, wherein the cabinet can be disassembled into one bounding-frame subassembly with its embedding heads facing upward, the door, the back-board, plural connecting-beam, screws, other bounding-frame subassembly with its embedding heads facing downward, put them together in turn, the two folded bounding-frame subassemblies are placed in opposite stacks to form a flat box for easy packing.
